(19) United States
(12) Patent Application Publication
(10) Pub. No.: US 2011/0304379 A1
(43) Pub. Date: Dec. 15, 2011

(54) SIGNAL MATCHING MODULE WITH COMBINATION OF ELECTRONIC COMPONENTS FOR SIGNAL MATCHING OF SINGLE OR MULTIPLE SUBSYSTEMS

(75) Inventors: CHUNG ER HUANG, NEW TAIPEI CITY (TW); HUANG CHAN CHIEN, NEW TAIPEI CITY (TW)

(73) Assignee: AZUREWAVE TECHNOLOGIES, INC., NEW TAIPEI CITY (TW)

(21) Appl. No.: 13/217,501

(22) Filed: Aug. 25, 2011

Related U.S. Application Data
(63) Continuation-in-part of application No. 11/976,938, filed on Oct. 30, 2007.

(51) Int. Cl. H03K 17/16

(52) U.S. Cl. 327/379

(57) ABSTRACT

A signal matching module for a single or multiple subsystems is disclosed. The signal matching module includes a plurality of electronic components with a first part of the electronic components categorized into external electronic components and a second part of the electronic components categorized into internal components. Each of the electronic components may correspond to a switch that is controllable by a corresponding control pin. And the external electronic components may be used to compensate the internal electronic components when the latter fail to cause the impedance to reach the desired level. One of the embodiments is to provide a unit cell which is used to connect with one or multiple subsystems, and an external communication port to which the external electronic components are connected serving as a feeding point for the purpose of better impedance matching.

### REFERENCE TO RELATED APPLICATIONS

This Application is being filed as a Continuation-in-Part of patent application Ser. No. 11/976,938, filed 30 Oct. 2007, currently pending.

### BACKGROUND OF THE INVENTION

1. Field of the Invention

The present invention discloses a signal matching module with combination of a plurality of electronic components for signal matching of single or multiple subsystems, more particularly, to a signal matching module disposed in a wireless communication module having the single or multiple subsystems, so as to reach a required matching without performance loss.

2. Description of Related Art

A high-frequency wireless communication module is often susceptible to home-grown interferences, which undoubtedly negatively affect the performance of the wireless communication module. Such interferences may take place more frequently when multiple subsystems, such as Wi-Fi, Bluetooth, GSM (Global System for Mobile Communication), WiMAX (Worldwide Interoperability for Microwave Access) and the like are coupled together.

For minimizing the effect of the interferences and even preventing the interferences from taking place, a switch or a circulator is usually used for switching signal paths of received and transmitted signals in a conventional wireless communication device with a high-frequency module and several wireless communication networks installed.

U.S. Pat. No. 6,894,562 ('562 patent) illustrates a conventional circulator applied to a high-frequency wireless communication module. More specifically, '562 patent discloses a divider that divides an input high-frequency signal into two output signals, and the circulator that adjusts the effect of signal amplifying. Reference is made to FIG. 1 in which a high-frequency signal is fed into an input terminal 1, and outputted from an output terminal 2. A divider 3 divides the high-frequency signal fed from the input terminal 1 into two signals along different signaling paths, one of which is transmitted along a first path through a primary amplifier 4, and the other is transmitted along a second path through a secondary amplifier 5. A circulator 6 is provided to relay the high-frequency signal from the secondary amplifier 5 (or transmitted along the second path) to the output terminal of the primary amplifier 4, i.e. the dotted line shown in the diagram. The high-frequency signal outputted from the primary amplifier 4 is also transmitted to the output terminal 2.

In a related technology regarding a communication device having multiple wireless communication subsystems, a switch is often used to switch the communication signals among the subsystems. FIG. 2 shows a schematic diagram of the mentioned communication device. The communication device includes a first communication module 25 and a second communication module 26. The first communication module 25 utilizes a bidirectional transmission line for the reception and the transmission of signals (RX/TX). The second communication module 26, on the other hand, utilizes a first transmission line for the reception of the signal (RX) and another transmission line for the transmission of the signal (TX). Both communication modules 25 and 26 are further coupled to a coupler 22 so that the transmission lines of the first communication module 25 and the second communication module 26 may be coupled together. The example shows that the switch 20 switches the signal directed by the coupler 22 and the signal transmitted by the second communication module 26 to the antenna 21.

The first communication module 25 can be implemented in terms of a Bluetooth module associated with the bidirectional transmission line for transmitting and receiving the signals. The second communication module 26 can be a wireless network (WiFi) module associated with the transmission lines for respectively transmitting and receiving the signals. The switch 20 is used for switching the signals received from the antenna 21 to the communication module based on the types of the received signals from the antenna 21, before guiding the signals to the communication modules 25 and 26. Meanwhile, the signals sent from the communication modules 25 and 26 are transmitted via the coupler 22, switch 20 and the antenna 21.

With the development of the technologies, many wireless communication subsystems can be installed in one communication module including the mentioned wireless communication network, Bluetooth, GSM and WiMAX. Those subsystems, however, may interfere with each other when operating simultaneously. The aforementioned interference may get worse when the subsystems share the same communication port for input/output purpose.

### SUMMARY OF THE INVENTION

According to the foregoing shortcomings of a conventional communication module with multiple subsystems, one common port adopted for the system may cause interferences among the subsystems and the performance of the communication to deteriorate. However, the present invention provides a signal matching module with a plurality of electronic components for the signal matching of the subsystems, which may in a flexible fashion provide the subsystems with more than one I/O port, eliminating the necessity of altering circuitry of the original communication module while achieving the goal of the signal matching between the subsystems.

For achieving the goal of the signal matching between the subsystems, the electronic components of the signal matching module may be categorized into external components and internal components according to a predetermined reference plane. The external electronic components may be used to compensate the internal matching electronic components when the latter fail to cause the impedance to reach the desired level for the signal matching purpose. When the internal electronic components standing alone could serve the purpose of the signal matching, the signal matching module could further help the system meet the requirement of quality factor and bandwidth.

The signal matching module includes a unit cell which has a plurality of interconnected electronic components and/or transmission lines. For example, a plurality of parallel-connected inductors are provided, and controlled by some external control pins. Further, a plurality of serially-connected capacitors may also be provided and controlled by some other control pins. Those control pins are electrically connected to the electronic components via switches, which are turned on or off by the control pins.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 shows a schematic diagram of a circular for the prior art;

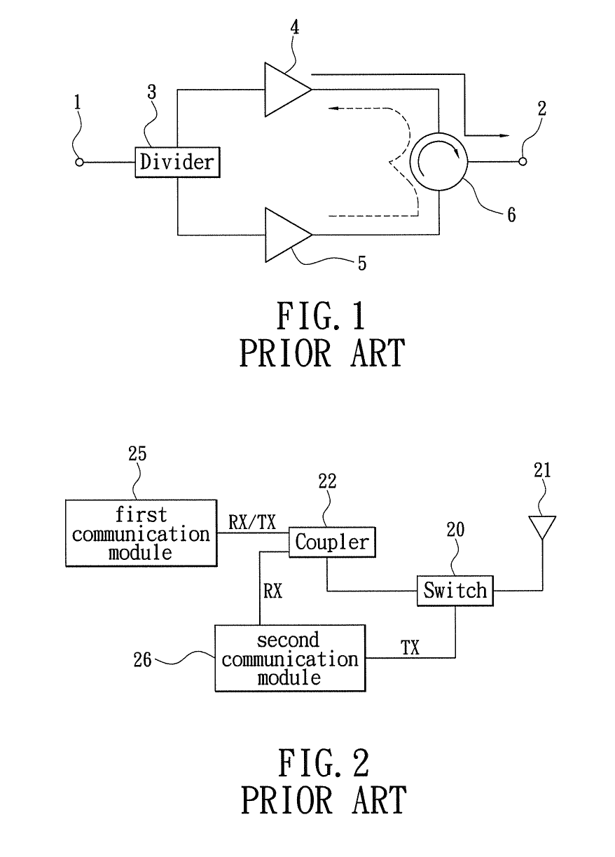

FIG. 2 shows a schematic diagram of the multiple subsystems of the prior art;

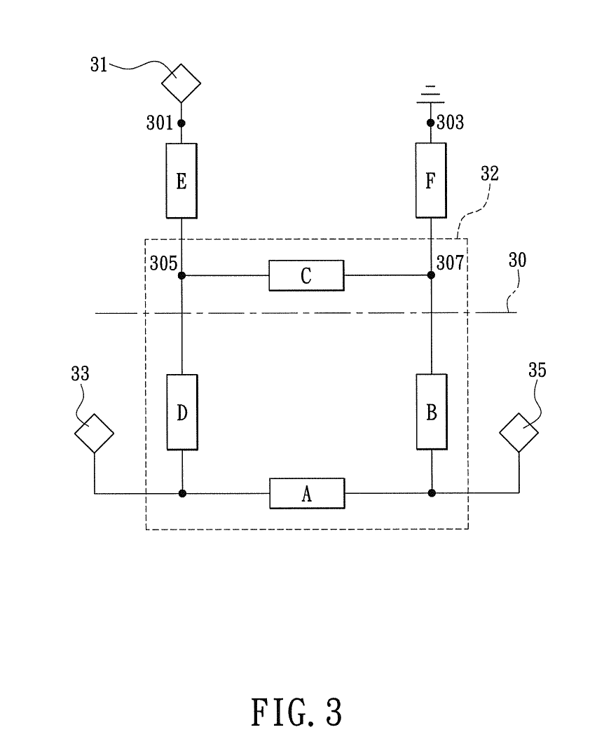

FIG. 3 shows a schematic diagram of a unit cell in a signal matching module according to one embodiment of the present invention;

FIG. 4A and FIG. 4B shows a schematic diagram of the unit cell of the signal matching module of the present invention;

FIG. 5A and FIG. 5B are the charts showing curves of insertion losses in the frequency domain for the unit cell;

FIG. 6A and FIG. 6B show the schematic diagram of the unit cell of the signal matching module of the present invention;

FIG. 7A and FIG. 7B are charts showing the curves of the insertion losses in the frequency domain for the unit cell;

FIG. 8 shows a Smith Chart for a multi-order matching;

FIG. 9A through FIG. 9C are the charts showing the curves between the insertion losses in the frequency domain associated with conventional arts using a general matching circuit and a unit cell of the present invention, respectively;

FIG. 10 shows a schematic diagram of the signal matching module of the embodiment of the present invention;

FIG. 11 shows one further schematic diagram of the unit cell according to one embodiment of the present invention.

### DETAILED DESCRIPTION OF THE PREFERRED EMBODIMENTS

The present invention is illustrated with a preferred embodiment and attached drawings. However, the invention is not intended to be limited thereby.

The present invention provides a signal matching module for a single or multiple subsystems within a communication module.

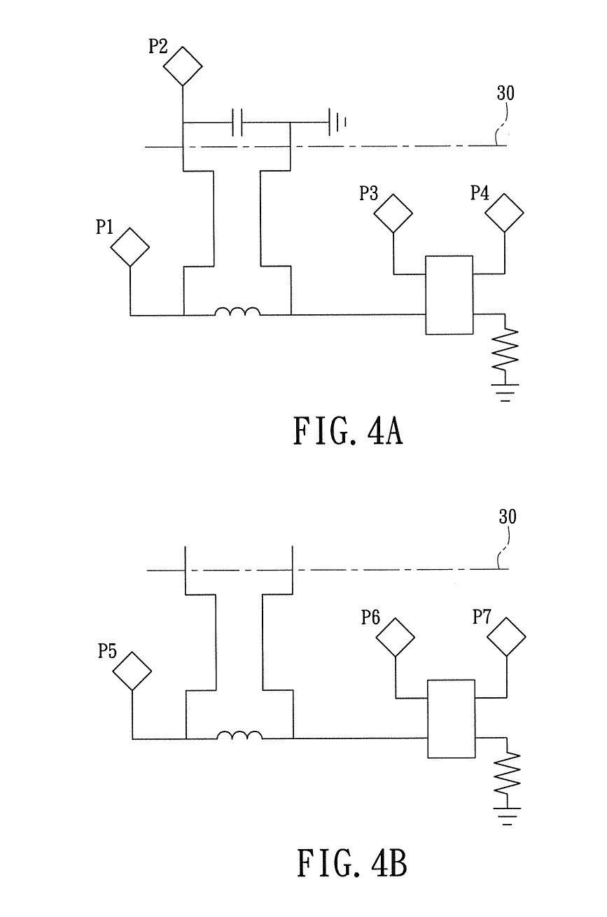

Reference is made to FIG. 3, which shows a schematic diagram of a unit cell 32 in a signal matching module according to one embodiment of the present invention. The unit cell 32 is used to connect to multiple subsystems, or to one subsystem. The unit cell 32 is implemented as an interface apparatus connecting with each subsystem. The unit cell 32 electrically connects to an internal communication port or to an external communication port. The labels of “external” and “internal” are based upon the locations of the communication port and will be further discussed in the subsequent paragraphs. And electronic components of the signal matching module may be categorized into “internal” and “external” groups depending on the locations of the electronic components also. The exemplary embodiment shows one external communication port to which the signal matching module is connected. The unit cell 32 at least includes interconnected electronic components or transmission lines, and connects to an external signaling source through the external communication port. For example, the external signaling source may be from a device that generates communication signals. Therefore, no extra loading associated with the external signaling source may result from the perspective of the subsystem connected to the internal electronic components, and the direct interference or signal loss can be avoided.

The unit cell 32 at least includes a first electronic component A, a second electronic component B, a third electronic component C, a fourth component D, a fifth electronic component E and a sixth electronic component F may be a general passive component such as a resistor, a capacitor and an inductor. In another implementation, the components A-E could be a transmission line. In the diagram, at least one connecting terminal (301, 303, 305, or 307) is used to connect with other subsystem above a reference plane 30 presented by dotted line. As previously mentioned, the subsystem that is above the reference plane may be labeled as the “external” subsystem.

Further, a communication port 31 for the subsystem is defined above the reference plane 30 and that particular communication port 31 may be categorized as the “external” communication port. The communication port 31 electrically connects to the unit cell 32 through one or more connecting terminals 305 and 307 as feeding points of the signal matching module for the signal matching purpose. Therefore, the unit cell 32 may be capable of compensating the internal electronic components (i.e., the electronic components under the reference plane 30) when the internal electronic components fail the matching, without extra loading caused on the part of the subsystem to which the signal matching module is connected. In addition, two other communication ports 33 and 35 are defined below the reference plane 30, for connecting the internal subsystems.

According to one of the embodiments, a combination of the plurality of unit cells 32 collectively forms a multi-order matching circuit. The multi-order signal matching circuit is configured to reach the required quality factor (Q-value), and then the bandwidth can be tuned by the matching.

In particular, the communication port 31 that connects to the external communication subsystem can process the tuning externally, and in doing so the inner communication module/system would not be affected by any signal loss, or interference.

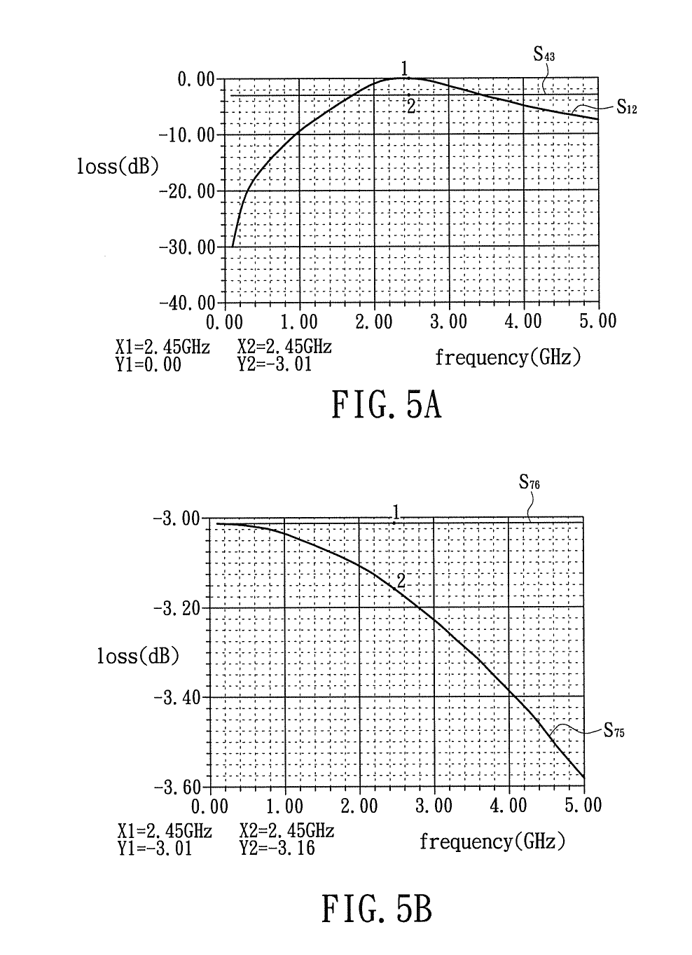

Next, FIG. 4A and FIG. 4B show two schematic diagrams of the unit cell of the signal matching module for the single or multiple subsystems of the present invention. The unit cell has a horizontal dotted line presenting a reference plane 30, and the electronic components under the reference plane 30 may be categorized as the internal electronic components. As such, a first port P1, a third port P3 and a fourth port P4 therein are used to connect with the internal subsystems, which refer to the subsystems under the reference plane 30. For example, the ports connect with various subsystems, especially to the wireless communication systems including WiFi, Bluetooth, GSM, UWB (Ultra Wide Band), DVB (Digital Video Broadcasting), GPS, 3G and WiMAX. Moreover, a second port P2 is disposed above the reference plane 30 for connecting with at least one external subsystem. FIG. 4B shows a schematic diagram of another unit cell. The unit cell has a fifth port P5, a sixth port P6 and a seventh port P7 which are disposed under the reference plane 30 and may be referred to as the internal ports connecting to the internal subsystems of the wireless communication module.

The mentioned reference plane 30 may be predetermined. In other words, the reference plane 30 may be vertical (not shown) so that the ports P1 and P2 may be the external ports while the ports P3 and P4 may fall into the category of “internal ports.” In a communication system, a feeding point is defined above the reference plane 30 and outside of the unit cell such as the second port P2 shown in FIG. 4A. If the internal electronic components fail the required matching, the external electronic components may help compensate the internal electronic components with the feeding point receiving the signaling source, so that the loss or the interference can be avoided on the part of the internal subsystem. Even though the internal electronic components collectively achieve the required matching, the multi-order signal matching circuit of the signal matching module may help reach the required quality factor (Q-value), causing the bandwidth to be tuned to the desired level.

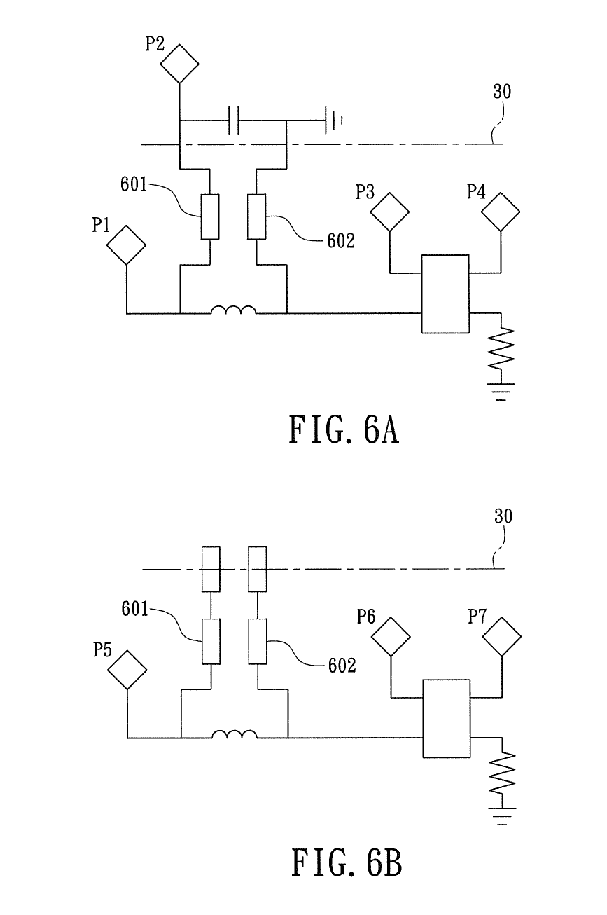

FIG. 5A shows a chart having a curve presenting an insertion loss in a frequency domain as the signals are transmitted among the ports in an ideal circuit. A default insertion loss of an internal circuit is set −3 dB. The internal circuit is defined to have the internal electronic components of the signal matching module and the internal subsystem. The chart shown in FIG. 5B presents a curve of S-parameter that is a fundamental measurement parameter in the process of RF design, thereby to simulate the behavior of an electronic component under different frequencies.

The curve S₄₃ presents the insertion loss of the signal emitted from the third port P3 and received via the fourth port P4. Since the third port P3 and the fourth port P4 are the internal communication ports the insertion loss is about −3.01 dBat the frequency 2.45 GHz.

The curve S₁₂ presents the insertion loss of the signal emitted from the second port P2, and received through the first port P 1. The insertion loss approaches zero at point 1 of curve S₁₂ (or at the frequency of 2.45 GHz), indicative of smaller insertion loss when compared with curve S₄₃. Therefore, the signal matching module for the single or multiple subsystems of the present invention has better performance because of the presence of the external electronic components that are capable of compensating the internal electronic components in the signal matching.

According to the embodiment shown in FIG. 4B, FIG. 5B shows a curve presenting the insertion loss in the frequency domain as the signal is transmitted among the ports in an ideal circuit. A default loss for the inner circuit is −3 dB.

The curve S₇₆ presents the insertion loss of the signal emitted from the sixth port P6 and received through the seventh port P7. Since the default loss for the internal circuit is −3 dB, the insertion loss standing at −3.01 dB does not change much at the point 1 (or at the frequency of 2.4 GHz).

The curve S₇₅ presents the insertion loss of the signal emitted from the fifth port P5 and received via the seventh port P7. But the insertion loss, which is −3.16 dB, is still around the default loss at point 2 (or at the frequency of 2.4 GHz).

Therefore, the signal matching module of the present invention may reduce the insertion loss and prevent the interference caused on the part of the internal circuit.

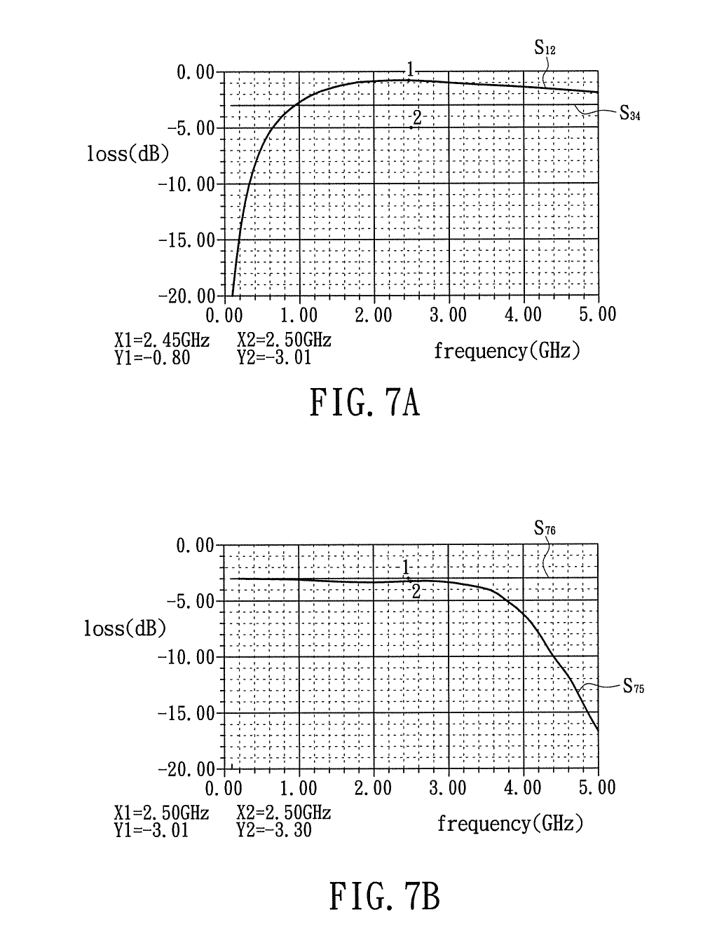

FIG. 6A and FIG. 6B show a block diagram of the signal matching module with a transmission line effect for the single or multiple subsystems.

In the embodiment of the unit cell shown in FIG. 6A, an external communication port above the reference plane 30 (e.g., a second port P2) is shown. The internal circuit may be associated with a first port P1, a third port P3 and a fourth port P4 under the reference plane 30. Beside the ordinary electronic components in the circuit, the effects of the transmission line such as a first transmission line module 601 and a second transmission line module 602 is under consideration. The first transmission line module 601 and the second transmission line module 602 are for connecting to the line between the internal circuit and the external circuit. Further, in addition to the transmission line the coupling effect between the first transmission line module 601 and the second transmission line module 602 may play the role of affecting the performance of the entire circuitry. For example, dielectric loss arising out of the un-matching impedance or the coupling effect between the two transmission lines may have negative impact on the circuitry.

Next, FIG. 6B has no the external communication port with the fifth port P5, the sixth port P6 and the seventh port P7 serving as the communication ports for the internal circuit. Even so, the internal circuit may be affected by the coupling effect between the first transmission line module 601 and the second transmission line module 602.

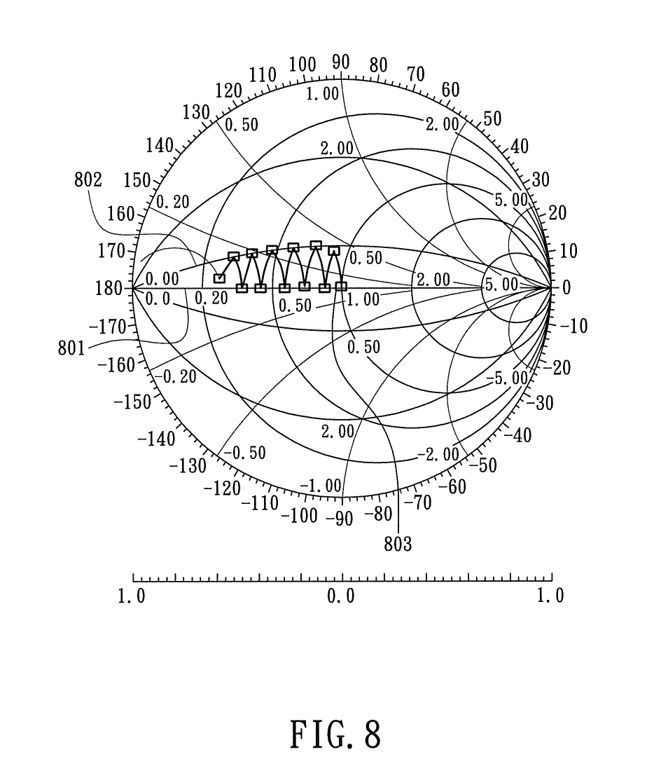

Furthermore, FIG. 7A and FIG. 7B show the curves presenting the relation between the insertion losses in the frequency domain when the transmission line effect is under consideration. In this exemplary embodiment, the default insertion loss associated with the transmission line effect is −3 dB.

FIG. 7A shows a curve representing the insertion loss between the communication ports shown in FIG. 6A. More specifically, point 1 and point 2 present the loss around the frequency of 2.45 GHz. In this embodiment, the curve S₁₂ indicates the behavior of the signals transmitted from the second port P2 and received by the first port P1. The point 1 indicates the insertion loss of −0.80 dB, suggesting the external communication port serving as the feeding point could be helping reduce the insertion loss. Meanwhile, the curve S₃₄ indicates the behavior of the signals transmitted from the fourth port P4 and received by the third port P3. Since the ports P3 and P4 are the internal ports, the corresponding insertion loss therefore may be close to the insertion loss in consideration of the transmission line effect, such as the loss of −3.01 dB shown in point 2 at frequency 2.50 GHz.

On the other hand, FIG. 7B shows the curves representing the insertion loss between the communication ports shown in FIG. 6B. In this embodiment, the curve S₇₆ indicates the insertion loss between the sixth port P6 and the seventh port P7. The signals are transmitted from the sixth port P6 and received by the seventh port P7. Since the ports P6 and P7 are part of the internal circuit, the insertion loss is similar to the default loss value −3 dB in consideration of the transmission line effect and the insertion loss tends not to vary between the frequencies of 0 to 5 GHz with the point 1 presenting the insertion loss of −3.01 dB at the frequency of 2.50 GHz. The curve S₇₅ indicates the behavior of the signals transmitted from the fifth port P5 and received by the seventh port P7. FIG. 6B shows that more interference occurs when the signal is transmitted between the ports P5 and P7, evidenced by the insertion loss of −3.30 dB at frequency 2.50 GHz (point 2). Despite a large insertion loss (e.g., −17 dB) that takes place at the frequency of 5 GHz as the result of the transmission line effect the overall behavior of the signal transmitted between the ports P7 and P5 is still associated with the desired insertion loss around the frequency of 2.5 GHz.

According to the experimental result shown in FIG. 7A and FIG. 7B with the transmission line effect taken into account, the second port P2 shown in FIG. 6 may function as a feeding point (or the external port) in order to lead to a lower insertion loss (0.8 dB in this embodiment). Under this arrangement, significant changes to the internal circuit may not be necessary. Therefore, the signal matching module of the present invention can reduce the insertion loss effectively and present the interference caused on the part of the internal circuit. Similarly, the interference occurred among the subsystems can be reduced if the invention is applied to the multiple subsystems.

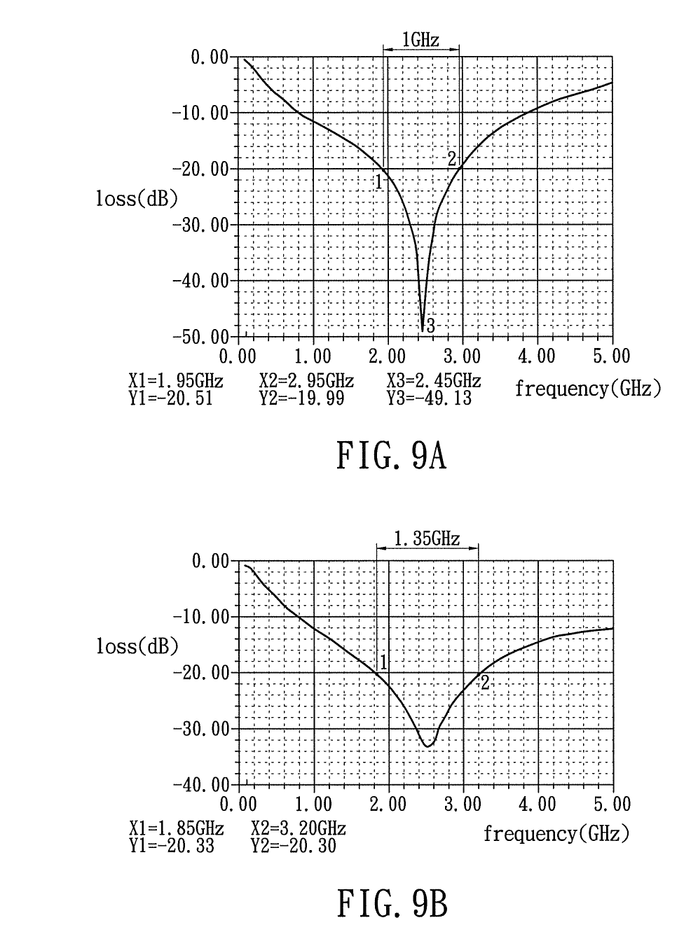

Reference is made to a Smith Chart shown in FIG. 8. The external circuit may be further used to perform a multi-order matching, so as to reach a required quality factor (Q-value) and to tune the bandwidth.

FIG. 8 shows a saw-tooth-shaped track of the impedance associated with the plurality of unit cells. For example, one time back-and-forth tuning means it uses the unit cell shown in FIG. 3 to tune the impedance matching in the circuit. The unit cells are used to tune the impedance to the required impedance level and the corresponding bandwidth.

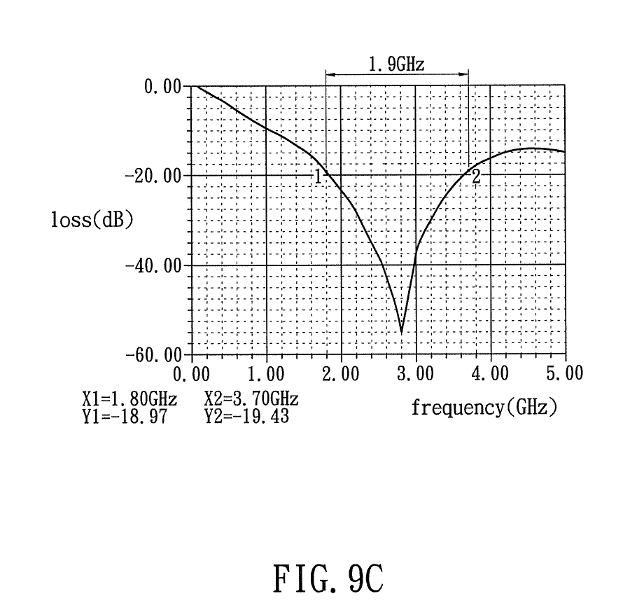

According to the S-parameter shown in the Smith Chart and the curve presenting the insertion loss, the Q-value can be controlled under 0.5 by the multi-order matching circuit. In the meantime, the reflective value, that is the insertion loss, can be controlled at −20 dB, and the bandwidth can reach 1.9 GHz. Reference is made to FIG. 9A, that shows a curve presenting the relation of bandwidth and insertion loss of a conventional art that uses a general matching circuit. Specifically, the insertion loss is controlled to −20 dB with the bandwidth staying at 1 GHz. In contradistinction, FIG. 9B shows an embodiment with the insertion loss being controlled to around −20 dB, the Q-value being smaller than 0.5, and the bandwidth being around 1.35 GHz by utilizing a matching circuit formed by a unit cell. Further, FIG. 9C shows an embodiment that utilizes the mentioned multi-order matching circuit to stay the Q-value under 0.5, the insertion loss around −20 dB, and the bandwidth around 1.9 GHz.

Based on the result of the experiment, the signal matching module of the present invention can flexibly tune the impedance matching of the entire communication module so as to reach the required matching. Obviously, the bandwidth of the system with the signal matching module of the present invention incorporated is better than the bandwidth of the system with the conventional signal matching circuit.

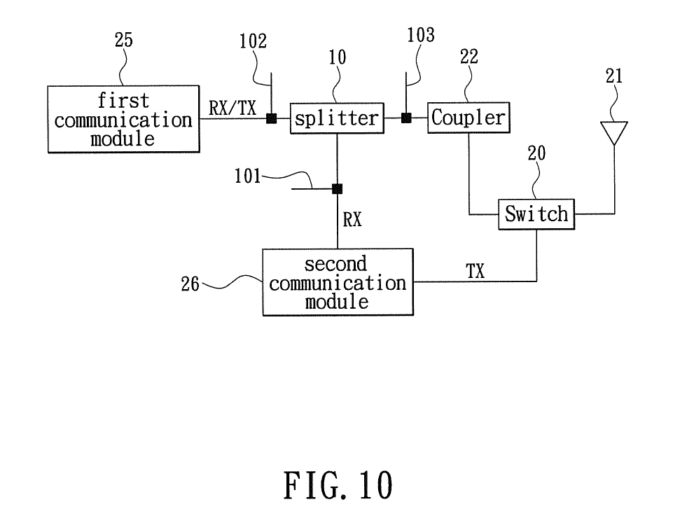

A block diagram the signal matching module of the present invention is shown in FIG. 10. A communication module having multiple wireless communication subsystems including a first communication module 25 and a second communication module 26 is provided. A switch 20 is used to switch the communication signals among the subsystems. The first communication module 25 is used to receive and transmit the communication signals via a duplex transmission line (RX/TX). The communication module 26 uses a transmission line (RX) and another transmission line (TX) for the signal communication purpose. These two communication modules utilize a coupler 22 to couple with the RX/TX transmission line for the first communication module 25 and the transmission line (RX) for the second communication module 26. A splitter 10 is used to discriminate the signals, and further to dispatch the signals to the switch 20 where the signals are switched and coupled to an antenna 21. In the embodiment, the signal matching module is used to connect with the transmission line coupling with the electronic component such as a first matching module 101 disposed on the transmission line between the splitter 10 and the second communication module 26, and a second matching module 102 between the splitter 10 and the first communication module 25, and a third matching module 103 between the splitter 10 and the coupler 22. In the preferred embodiment of the present invention, the mentioned first communication module 25 can be, but not limited to, a Bluetooth module that features the duplex transmission line. The second communication module 26 can be, but not limited to, a WiFi module that has two separate transmission lines.

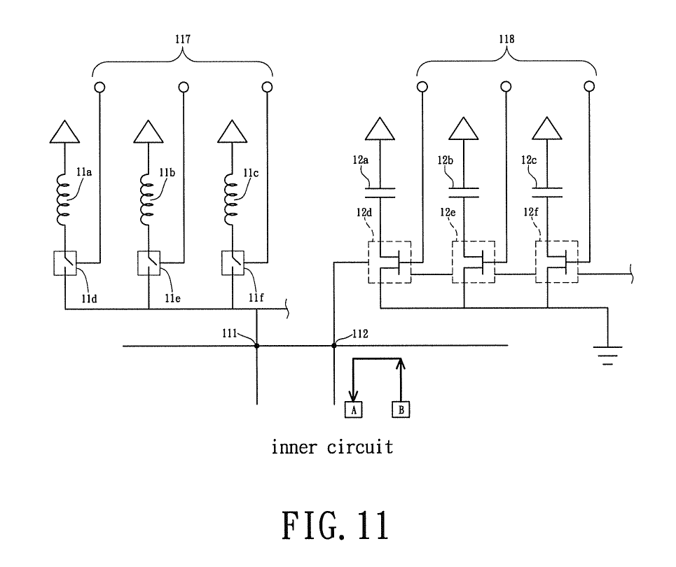

Reference is made to FIG. 11 showing one further embodiment of the present invention, in which a plurality of electronic components are disposed in the unit cell used in the signal matching module.

In the present example, two feeding points including a first feeding point 111 and a second feeding point 112 are provided for the internal circuit to link the external circuit. The shown unit cell includes at least two feeding points 111 and 112 respectively connected with the electronic components such as the inductors 11a, 11b, and 11c and capacitors 12a, 12b, and 12c.

Exemplarily, the inductors 11a, 11b, and 11c are connected to the feeding point 111 via the respective switches 11d, 11e, and 11f, and under control through a set of external control pins 117. The inductors 11a, 11b, and 11c are exemplarily connected in parallel. As shown in the diagram, the inductors 11a, 11b, and 11c are connected to the feeding point 111 through the switches 11d, 11e, and 11f. The control pins 117 are electrically linked to the switches 11d, 11e, and 11f, and respectively provided for switching on or off the inductors 11a, 11b, and/or 11c. When in operation, the unit cell may cause one or more inductors 11a, 11b, and 11c to be incorporated through the operations of the control pins 117, for tuning the system to cause the impedance to reach the desired level.

On the other hand, the feeding point 112 may be connecting to the capacitors 12a, 12b, and 12c. These capacitors 12a, 12b, and 12c are exemplarily connected in series, especially through a plurality switches 12d, 12e, and 12f. The feeding point 112 is electrically connected to the capacitors 12a, 12b, and 12c via the switches 12d, 12e, and 12f, with each of the switches corresponding to each of the capacitors. Further, a set of control pins 118 are directly linked to those switches 12d, 12e, and 12f, and provided for switching on or off the connections between the capacitors 12a, 12b, and 12c and the feeding point 112. Similarly, while the signal matching module having the unit cell is in operation, the control pins 118 may be configured to cause one or more capacitors 12a, 12b, and 12c to be incorporated for the system to reach the required impedance.

As a whole, for reaching the required impedance for the system, the inductors 11a, 11b, 11c and the capacitors 12a, 12b, and 12c may be selected through the external control pins 117 and 118. With the combination of a certain number of the inductors (for example, 11a, 11b, 11c) and the capacitors (for example, 12a, 12b, and 12c), the signal matching module in accordance with the present invention may help cause the impedance to the desired level for the signal matching purpose.

Also, a combination of the plurality of the unit cells shown in FIG. 11 forms a multi-order matching circuit.

Furthermore, the signal matching module may be used to tune an external communication system. Detectors A and B are interconnected over a transmission line, and configured to electrically connect to the external communication system. As shown in the diagram, the detector A is configured to bridge a power source for the communication system and the unit cell of signal matching module. As such, the detector A receives the voltage signal from the power source. A transmission line is linked between the detector A and the detector B. The coupling effect may result across the transmission line between the detector A and detector B and the unit cell.

Due to the coupling across the transmission line and the unit cell, the detector B may then receive the signal affected by the coupling effect.

The signal matching module in accordance with the present invention is used to tune the suitable impedance for the communication system by configuring the electronic components. In the present example, the ratio between the signals received by detector A and the detector B (B/A) may provide a reference for the tuning of the impedance. More specifically, the ratio between the signals received at the detectors A and B may serve as the basis according to which the electronic components including 11a, 11b, 11c, 12a, 12b, and 12c are switched on/off via the operations of the external control pins.

While the invention has been described by means of a specification with accompanying drawings of specific embodiments, numerous modifications and variations could be made thereto by those skilled in the art without departing from the scope and spirit of the invention set forth in the claims.

What is claimed is:

1. A signal matching module for matching a sub-system within a wireless communication module, comprising:
(1) a unit cell connected with the subsystem, the unit cell having a plurality of interconnected electronic components, wherein the interconnected electronic components include:
a plurality of capacitors, each of which is connected with a first switch;
a plurality of inductors, each of which is connected with a second switch; and
two sets of control pins electrically connected to the first switches and the second switches, for selecting the capacitor and/or the inductor;
(2) a communication port electrically connected with the unit cell for connecting to a signaling source; and
(3) one or more feeding points connected with the unit cell, and respectively connected with the interconnected electronic components including inductors and capacitors, via the first switches and the second switches;
wherein the signal matching module connects with an external signaling sources through a feeding point.

2. The signal matching module of the claim 1, further comprising a plurality of terminals for connecting to other communication ports, circuits, modules or grounds.

3. The signal matching module of claim 1, wherein a multi-order matching circuit is formed by combining the plurality of unit cells, for preparing a required quality factor and bandwidth.

4. The signal matching module of claim 1, wherein the communication port is categorized as an external communication port when a first part of the electronic components electrically connected to the communication port are considered as external electronic component for signal matching purpose, and the communication port is labeled as an internal communication port when a second part of the electronic components electrically connected to the communication port are considered as internal electronic components.

5. The signal matching module of claim 4, wherein the subsystem is selected from a group consisted of WiFi, Bluetooth, GSM, UWB, DVB, GPS, 3G and WiMAX.

6. The signal matching module of claim 4, wherein the feeding point electrically connects to the external electronic components of the signal matching module for compensating the internal electronic components of the signal matching module when the internal matching components collectively fails to achieve a required matching.

7. The signal matching module of claim 6, wherein the operations of the first switches and the second switches are through the control pins.

8. The signal matching module of claim 1, wherein the capacitors are interconnected in series through the first switches and the second switches.

9. The signal matching module of claim 8, wherein the first switches and the second switches are transistors.

10. The signal matching module of claim 1, wherein the inductors are interconnected in parallel through the first switches and the second switches.
